(19) United States
(12) Patent Application Publication
(10) Pub. No.: US 2025/0176220 A1
(43) Pub. Date: May 29, 2025

(54) LAMINATED STRUCTURE AND THIN FILM TRANSISTOR

(71) Applicants: Japan Display Inc., Tokyo (JP); IDEMITSU KOSAN CO., LTD., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Emi KAWASHIMA, Tokyo (JP); Yuki TSURUMA, Tokyo (JP); Daichi SASAKI, Tokyo (JP)

(73) Assignees: Japan Display Inc., Tokyo (JP); IDEMITSU KOSAN CO., LTD., Tokyo (JP)

(21) Appl. No.: 19/039,202

(22) Filed: Jan. 28, 2025

Related U.S. Application Data
(63) Continuation of application No. PCT/JP2023/027457, filed on Jul. 26, 2023.

(30) Foreign Application Priority Data
Aug. 1, 2022 (JP) 2022-122911

(51) Int. Cl. H10D 30/67; H10D 30/01; H10D 62/40; H10D 62/80; H10D 86/60

(52) U.S. Cl. CPC H10D 30/6755; H10D 30/6704; H10D 62/40; H10D 62/875; H10D 30/031; H10D 30/6734; H10D 86/60

(57) ABSTRACT

The laminated structure has a base insulating layer, a metal oxide layer arranged on the base insulating layer, and an oxide semiconductor layer arranged in contact with the metal oxide layer, and the oxide semiconductor layer has a first region in which the same metal element as the metal element contained in the metal oxide layer has the concentration gradient, and the concentration gradient of the metal element increases as it approaches the interface between the metal oxide layer and the oxide semiconductor layer.

### CROSS-REFERENCE TO RELATED APPLICATIONS

This application is a Continuation of International Patent Application No. PCT/JP2023/027457, filed on Jul. 26, 2023, which claims the benefit of priority to Japanese Patent Application No. 2022-122911, filed on Aug. 1, 2022, the entire contents of each are incorporated herein by reference.

### FIELD

An embodiment of the present invention relates to a laminated structure including an oxide semiconductor layer having a polycrystalline structure. In addition, an embodiment of the present invention relates to a thin film transistor including the laminated structure.

### BACKGROUND

In recent years, a thin film transistor using an oxide semiconductor film as a channel has been developed instead of a silicon semiconductor film such as amorphous silicon, low-temperature polysilicon, and single-crystal silicon (see, for example, Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, Japanese laid-open patent publication No. 2021-108405). The thin film transistor including such an oxide semiconductor layer can be formed in a simple-structure and low-temperature process as well as a thin film transistor including an amorphous silicon film. In addition, the thin film transistor including the oxide semiconductor layer is known to have higher mobility than the thin film transistor including the amorphous silicon film.

### SUMMARY

A laminated structure according to an embodiment of the present invention includes a base insulating layer, a metal oxide layer arranged on the base insulating layer, and an oxide semiconductor layer in contact with the metal oxide layer, and having a polycrystalline structure, wherein the oxide semiconductor layer includes a first region in which the same metal element as the metal element contained in the metal oxide layer has the concentration gradient, and the concentration gradient of the metal oxide layer increases as it approaches the interface between the metal oxide layer and the oxide semiconductor layer.

A thin film transistor according to an embodiment of the present invention includes a gate insulating film arranged on the oxide semiconductor layer; and a gate electrode arranged on the gate insulating film so as to overlap at least a part of the oxide semiconductor layer.

### BRIEF DESCRIPTION OF DRAWINGS

FIG. 1 is a schematic diagram showing a laminated structure according to an embodiment of the present invention.

FIG. 2 is a cross-sectional view showing an outline of a thin film transistor according to an embodiment of the present invention.

FIG. 3 is a cross-sectional view showing an outline of a thin film transistor according to an embodiment of the present invention.

FIG. 4 is a flowchart showing a method for manufacturing a thin film transistor according to an embodiment of the present invention.

FIG. 5 is a cross-sectional view showing a method for manufacturing a thin film transistor according to an embodiment of the present invention.

FIG. 6 is a cross-sectional view showing a method for manufacturing a thin film transistor according to an embodiment of the present invention.

FIG. 7 is a cross-sectional view showing a method for manufacturing a thin film transistor according to an embodiment of the present invention.

FIG. 8 is a cross-sectional view showing a method for manufacturing a thin film transistor according to an embodiment of the present invention.

FIG. 9 is a cross-sectional view showing a method for manufacturing a thin film transistor according to an embodiment of the present invention.

FIG. 10 is a cross-sectional view showing a method for manufacturing a thin film transistor according to an embodiment of the present invention.

FIG. 11 is a cross-sectional view showing a method for manufacturing a thin film transistor according to an embodiment of the present invention.

FIG. 12 is a cross-sectional view showing a method for manufacturing a thin film transistor according to an embodiment of the present invention.

FIG. 13 is a schematic diagram showing an electronic device according to an embodiment of the present invention.

FIG. 14 is a STEM image in the vicinity of a channel region of a thin film transistor in Example A.

FIG. 15 is a STEM image in the vicinity of a source region of a thin film transistor in Example A.

FIG. 16 is a STEM image in the vicinity of a channel region of a thin film transistor in Comparative Example A.

FIG. 17 is a STEM image in the vicinity of a source region of a thin film transistor in Comparative Example A.

FIG. 18 is the EDX analysis results of Al in the vicinity of a channel region of a thin film transistor in Example A.

FIG. 19 is the EDX analysis results of Al in the vicinity of a source region of a thin film transistor in Example A.

FIG. 20 is a graph obtained by fitting a profile of Al obtained by an EDX analysis in a channel region of Example A with a Gaussian function.

FIG. 21 is a graph obtained by fitting a profile of Al obtained by an EDX analysis in a source region of Example A with a Gaussian function.

FIG. 22 is a graph obtained by fitting a profile of Al obtained by an EDX analysis in a channel region of Example A with a complementary error function.

FIG. 23 is a graph obtained by fitting a profile of Al obtained by an EDX analysis in a source region of Example A with a complementary error function.

FIG. 24 is a graph obtained by fitting a profile of Al obtained by an EDX analysis in a channel region of Example A with a Lorentz function.

FIG. 25 is a graph obtained by fitting a profile of Al obtained by an EDX analysis in a source region of Example A with a Lorentz function.

FIG. 26 is the EDX analysis results of In in a channel region of a thin film transistor in Example A.

FIG. 27 is the EDX analysis results of In in the vicinity of a source region of a thin film transistor in Example A.

### DESCRIPTION OF EMBODIMENTS

However, the field-effect mobility of a thin film transistor including a conventional oxide semiconductor layer is not so high even when an oxide semiconductor layer having crystallinity is used. For this reason, it is desired to improve the crystal structure of the oxide semiconductor layer used in the thin film transistor and improve the field-effect mobility of the thin film transistor.

In view of the above, an object of an embodiment of the present invention is to provide a novel laminated structure including the oxide semiconductor layer having a polycrystalline structure. Another object is to provide a thin film transistor including the laminated structure.

Hereinafter, embodiments of the present invention will be described with reference to the drawings. The following disclosure is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the width, thickness, shape, and the like of each part in comparison with an actual embodiment. However, the illustrated shapes are merely examples, and do not limit the interpretation of the present invention. In the present specification and the drawings, the same reference signs are given to structure similar to those described above with respect to the above-described drawings, and detailed description thereof may be omitted as appropriate.

In the present specification and the like, a direction from a substrate toward an oxide semiconductor layer is referred to as “upper” or “above”. Conversely, a direction from the oxide semiconductor layer to the substrate is referred to as “lower” or “below”. In this way, although the phrase “above” or “below” is used for description for convenience of explanation, for example, the substrate and the oxide semiconductor layer may be arranged so that the upper and lower relationship is different to that shown in the drawings. In the following explanation, for example, an expression “oxide semiconductor layer on a substrate” merely describes the upper and lower relationship between the substrate and the oxide semiconductor layer as described above, and another member may be arranged between the substrate and the oxide semiconductor layer. Above or below means a stacking order in a structure in which a plurality of layers is stacked, and may be a positional relationship in which a thin film transistor and a pixel electrode do not overlap each other in a plan view when expressed as the pixel electrode above the thin film transistor. On the other hand, when expressed as the pixel electrode vertically above the thin film transistor, it means a positional relationship in which the thin film transistor and the pixel electrode overlap each other in a plan view.

In the present specification, the terms “film” and “layer” can optionally be interchanged with one another.

In the present specification and the like, a “semiconductor device” refers to any device that can function by utilizing semiconductor properties. The thin film transistor and a semiconductor circuit are one form of the semiconductor device. For example, the semiconductor device may be an integrated circuit (IC) such as a display device or micro-processing unit (MPU), or a thin film transistor used in a memory circuit.

In the present specification and the like, the “display device” refers to a structure that displays an image using an electro-optical layer. For example, the term display device may refer to a display panel that includes the electro-optical layer, or may refer to a structure with other optical members (for example, a polarized member, a backlight, a touch panel, and the like) attached to a display cell. The “electro-optical layer” may include a liquid crystal layer, an electroluminescent (EL) layer, an electrochromic (EC) layer, and an electrophoretic layer, unless there is no technical contradiction. Therefore, with respect to the embodiments described later, although a liquid crystal display device including a liquid crystal layer and an organic EL display device including an organic EL layer will be exemplified. However, the structure according to the embodiment can be applied to a display device including the other electro-optical layers described above.

In the present specification and the like, expressions “α includes A, B, or C,” “α includes any of A, B, and C,” and “α includes one selected from a group consisting of A, B, and C” do not exclude the case where α includes a plurality of combinations of A to C unless otherwise specified. Furthermore, these expressions do not exclude the case where α includes other elements.

In addition, the following embodiments may be combined with each other as long as there is no technical contradiction.

### First Embodiment

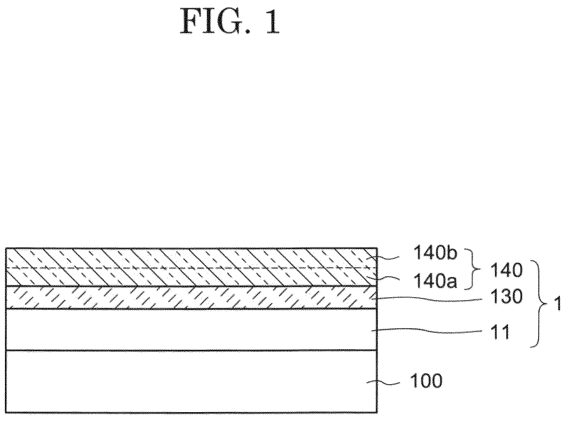

A laminated structure 1 according to an embodiment of the present invention will be described with reference to FIG. 1.

The laminated structure 1 according to an embodiment of the present invention includes a base insulating layer 11 arranged on a substrate 100, a metal oxide layer 130 (MO: Metal Oxide) arranged on the base insulating layer 11, and an oxide semiconductor layer 140 (OS: Oxide Semiconductor) arranged in contact with the metal oxide layer 130.

A rigid substrate having light transmittance such as a glass substrate, a quartz substrate, a sapphire substrate, or the like is used as the substrate 100. In the case where the substrate 100 needs to have flexibility, a substrate containing a resin such as a polyimide substrate, an acryl substrate, a siloxane substrate, or a fluororesin substrate is used as the substrate 100. In the case where the substrate containing a resin is used as the substrate 100, an impurity may be introduced into the resin in order to improve the heat resistance of the substrate 100.

A general insulating material is used as the base insulating layer 11.

For example, an inorganic insulating layer such as silicon oxide (SiOₓ), silicon oxynitride (SiOₓN_{y}), silicon nitride (SiNₓv), or silicon nitride oxide (SiNₓO_{y}), or a laminated film thereof is used as these insulating layers. For example, a thickness of the base insulating layer 11 is 50 nm or more and 300 nm or less, 60 nm or more and 200 nm or less, or 70 nm or more and 150 nm or less.

In addition, the above SiOₓN_{y} is a silicon compound and aluminum compound which contain a smaller proportion (x>y) of nitrogen (N) than oxygen (O). SiNₓO_{y} is a silicon compound containing a smaller proportion (x>y) of oxygen than nitrogen.

A metal element contained in the metal oxide layer 130 is preferably a metal element having an action of widening a band gap of the oxide semiconductor layer 140. Specifically, a metal oxide with a band gap of 4.0 eV or more is preferred, and one or more metal elements selected from aluminum (Al), magnesium (Mg), calcium (Ca), scandium (Sc), gallium (Ga), germanium (Ge), strontium (Sr), nickel (Ni), tantalum (Ta), yttrium (Y), zirconium (Zr), barium (Ba), hafnium (Hf), cobalt (Co), and lanthanoid-based elements are used as an example of the metal element. For example, a metal oxide layer containing aluminum as a main component may be used as the metal oxide layer 130. For example, an inorganic insulating layer such as aluminum oxide (AlOₓ), aluminum oxynitride (AlOₓN_{y}), aluminum nitride oxide (AlNₓO_{y}), and aluminum nitride (AlNₓ) are used as the metal oxide layer containing aluminum as a main component. The “metal oxide layer containing aluminum as a main component” means that the proportion of aluminum contained in the metal oxide layer 130 is 1% or more of the entire metal oxide layer 130. The proportion of aluminum contained in the metal oxide layer 130 may be 5% or more and 70% or less, 10% or more and 60% or less, or 30% or more and 50% or less of the entire metal oxide layer 130. The ratio may be a mass ratio or a weight ratio. For example, a thickness of the metal oxide layer 130 is 1nm or more and 100 nm or less, 1 nm or more and 50 nm or less, 1 nm or more and 30 nm or less, or 1 nm or more and 10 nm or less.

The oxide semiconductor layer 140 contains indium (In) and at least one or more metal (M) elements excluding indium. The composition ratio of an oxide semiconductor film is preferably such that an atomic ratio of indium and the at least one metal element satisfies Formula (1). In other words, the proportion of indium to the total metal element in the oxide semiconductor film is preferably 50% or more. By increasing the proportion of indium, an oxide semiconductor film having crystallinity can be formed. In addition, the crystal structure of the oxide semiconductor film preferably has a bixbyite-type structure. By increasing the proportion of indium, an oxide semiconductor film having the bixbyite-type structure can be formed.

$$[ Formula 1 ]$$

$$0.01 < \frac{[ M ]}{[ ln ] + [ M ]} < 0.5 \qquad ( 1 )$$

In addition, the metal element other than indium is not limited to one type of metal element. Elements other than indium may include a plurality of types of metal elements.

Although a detailed method for manufacturing the oxide semiconductor layer 140 will be described later, a film can be formed by a sputtering method using a sputtering target of an oxide semiconductor. The composition of the oxide semiconductor layer deposited by sputtering depends on the composition of the sputtering target. By using the sputtering target having the above-described composition, it is possible to form an oxide semiconductor layer having no composition deviation of the metal element by sputtering. Therefore, the composition of the metal element (for example, indium and another metal element) of the oxide semiconductor layer may be equivalent to the composition of the metal element of the sputtering target. For example, the composition of the metal element of the oxide semiconductor layer can be specified based on the composition of the metal element of the sputtering target. Since oxygen contained in the oxide semiconductor layer varies depending on the sputtering process conditions, it does not apply in this case.

In addition, the composition of the metal element of the oxide semiconductor layer 140 can also be specified using a fluorescent X-ray analysis or an Electron Probe Micro Analyzer (EPMA) analysis, and the like. Furthermore, since the oxide semiconductor layer 140 has a polycrystalline structure, the composition of the oxide semiconductor layer 140 may be specified using an X-ray Diffraction (XRD) method. Specifically, the composition of the metal element of the oxide semiconductor layer 140 can be specified based on the crystal structure and the lattice constant of the oxide semiconductor layer 140 obtained from the XRD method.

The oxide semiconductor layer 140 according to the present embodiment has a polycrystalline structure containing a plurality of crystal grains. Although details will be described later, by using a Poly-OS (Poly-crystalline Oxide Semiconductor) technique, it is possible to form the oxide semiconductor layer 140 having a new polycrystalline structure that is different from the conventional one. Therefore, in the following description, in order to distinguish from the oxide semiconductor layer 140 having the conventional polycrystalline structure, the oxide semiconductor layer 140 having the polycrystalline structure according to the present embodiment may be referred to as a Poly-OS film.

The crystalline structure of the Poly-OS film is not particularly limited, but preferably includes the bixbyite-type structure. The crystal structure of the Poly-OS film can be specified using the XRD method or an electron diffraction method. As described above, by increasing the proportion of indium in the oxide semiconductor layer 140, the Poly-OS film having the bixbyite-type structure can be formed.

In the present embodiment, the oxide semiconductor layer 140 is in contact with the metal oxide layer 130. Therefore, the oxide semiconductor layer 140 may contain a metal element derived from the metal oxide layer 130. That is, the oxide semiconductor layer 140 may contain the same metal element as the metal element contained in the metal oxide layer 130. In this case, it is preferable that the oxide semiconductor layer 140 has a region 140a in which the metal element contained in the metal oxide layer 130 has a concentration gradient, and the concentration gradient of the metal element increases toward the interface between the metal oxide layer 130 and the oxide semiconductor layer 140.

As described above, the metal element contained in the metal oxide layer 130 is a metal element having an action of widening the band gap. For example, a metal oxide with a band gap of 4.0 eV or more is preferably used for the metal oxide layer 130, and one or more metal elements selected from aluminum (Al), magnesium (Mg), calcium (Ca), scandium (Sc), gallium (Ga), germanium (Ge), strontium (Sr), nickel (Ni), tantalum (Ta), yttrium (Y), zirconium (Zr), barium (Ba), hafnium (Hf), cobalt (Co), and lanthanoid-based elements are used as the example of the metal element. When the metal element contained in the metal oxide layer 130 is diffused into the oxide semiconductor layer 140, the band gap is widened in the region 140a where the metal element is diffused. As a result, the region 140a in which the metal element is diffused in the oxide semiconductor layer 140 becomes a region acting like an insulator.

The oxide semiconductor layer 140 has a thickness of at least 15 nm or more, and the region 140a is a region less than 14 nm from the interface with the metal oxide layer 130 in a thickness direction of the oxide semiconductor layer 140.

The oxide semiconductor layer 140 has a thickness of at least 15 nm or more, and the oxide semiconductor layer 140 that does not have a concentration gradient of metal elements on the side that does not contact the metal oxide layer 130, and region 140b is in contact with region 140a and has a thickness of 1 nm or more in the thickness direction of the oxide semiconductor layer 140. In other words, the region 140b from the surface of the oxide semiconductor layer 140 to the region 140a is a region where the metal element has no concentration gradient.

For example, the concentration of the metal element contained in the metal oxide layer 130 and the oxide semiconductor layer 140 can be confirmed by, for example, Energy Dispersive X-ray Spectroscopy (EDX), or Secondary Ion Mass Spectrometry (SIMS), and the like. The concentration profile of the metal element obtained by EDX spectrometry can confirm the thickness of the oxide semiconductor layer 140 in the region 140a with the concentration gradient of the metal element.

The concentration gradient in a film thickness direction of the metal element contained in the metal oxide layer 130 and the oxide semiconductor layer 140 can be evaluated by TEM-EDX as follows.

First, the laminated structure or a TFT is FIB (Focused Ion Beam) processed at an acceleration voltage of 20 kV to 30 kV by a composite beam processing and observation device (JIB-4700F, manufactured by JEOL Ltd.), and then a thin film sample for observing a cross-sectional TEM is picked up by a micro sampling method at an acceleration voltage of 40 kV by a focused ion beam processing and observation device (FIB) (FB-2100, manufactured by Hitachi High-Tech Corporation.).

The thin film sample for observing the cross-sectional TEM is prepared as a thin film including the entire region of the metal oxide layer 130 and the oxide semiconductor layer 140 in the film thickness direction.

Next, a cross-sectional TEM of the thin film sample for observing the cross-sectional TEM is observed, and a gate insulating layer 120, the metal oxide layer 130, the oxide semiconductor layer 140, and a gate insulating layer 150 are subjected to an EDX line analysis in the thickness direction.

The EDX analysis is performed by an energy-dispersive X-ray analyzer (“JED-2300T” manufactured by JEOL Ltd.) under the following conditions.
Acceleration voltage: 200 kV
Measurement mode: STEM mode
Spot diameter: 0.16 nm
Measurement interval: 1 nm

The EDX analysis evaluates the concentration gradient of the metal element in the film thickness direction by performing the EDX line analysis by selecting all constituent elements of the gate insulating layer 120, the metal oxide layer 130, the oxide semiconductor layer 140, and the gate insulating layer 150 that are detectable by the device in addition to In and Al as the element to be detected (detectable element).

In this case, a thickness of a region in the oxide semiconductor layer 140 in which Al has the concentration gradient may be calculated using a fitting function. As described above, the region 140a in which the metal element has the concentration gradient is formed by diffusion of the metal element. Since the diffusion of the metal element in the region where the metal element has the concentration gradient is considered to be a Gaussian distribution, the profile of the metal element can be fitted using a Gaussian function (Formula (2)) or a complementary error function (Formula (3)).

$$[ Formula 2 ]$$

$$f ( x ) = A exp \{ - \frac{{( x - b )}^{2}}{2 {c}^{2}} \} \qquad ( 2 )$$

$$[ Formula 3 ]$$

$$f ( x ) = A erfc \{ \frac{( x - b )}{2 c} \} \qquad ( 3 )$$

In Formula (2) and Formula (3), the value b is an offset value for adjusting the position of the interface between the metal oxide layer 130 and the oxide semiconductor layer 140, and the value c is a scale parameter. In addition, the value A is the concentration of the metal element at the interface between the metal oxide layer 130 and the oxide semiconductor layer 140. The thickness Δd of the oxide semiconductor layer corresponding to the thickness Δd of the region where the metal element has the concentration gradient can be calculated based on the value c. For example, for the Gaussian function, a distance over which the concentration of the metal element varies by about 99.7% can be expressed as 3c. That is, in the fitting using the Gaussian function, by using Δd=3c, it is possible to cover most of Δd in the region where the metal element has the concentration gradient. The complementary error function is similar. Therefore, in the case where the fitting function is used, the thickness Δd in the region where the metal element has the concentration gradient can be calculated as Δd=3c.

The fitting function in the concentration profile of the metal element is not limited to the Gaussian function and the complementary error function. For example, a Lorentz function (Formula (4)) may be used as the fitting function.

$$[ Formula 4 ]$$

$$f ( x ) = A \frac{{c}^{2}}{{( x - b )}^{2} + {c}^{2}} \qquad ( 4 )$$

In Formula (4), the value A is the concentration of the metal element at the interface between the metal oxide layer 130 and the oxide semiconductor layer 140, b is an offset value, and c is the half width at half maximum. In this case, the thickness Δd may also be calculated as Δd=3c.

In addition, not all of the thicknesses Δd of the region with the concentration gradient of the metal element calculated using the fitting function act like an insulator. For example, a region having a thickness corresponding to c becomes a region acting like an insulator. That is, the region with the thickness corresponding to c corresponds to the region 140a in which the same metal element as the metal element contained in the metal oxide layer 130 has the concentration gradient.

The oxide semiconductor layer 140 contains indium and at least one metal element excluding indium, and the metal oxide layer 130 has a region containing indium.

Indium contained in the metal oxide layer 130 has the concentration gradient, and the concentration gradient of indium increases as it approaches the interface between the metal oxide layer and the oxide semiconductor layer 140.

### Second Embodiment

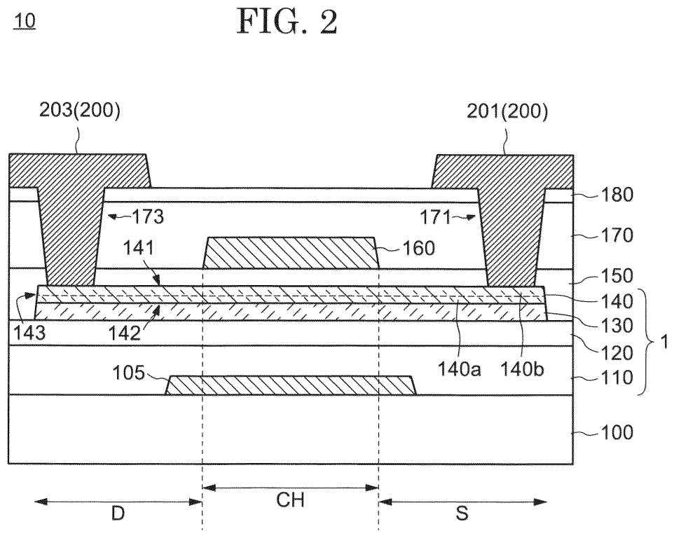

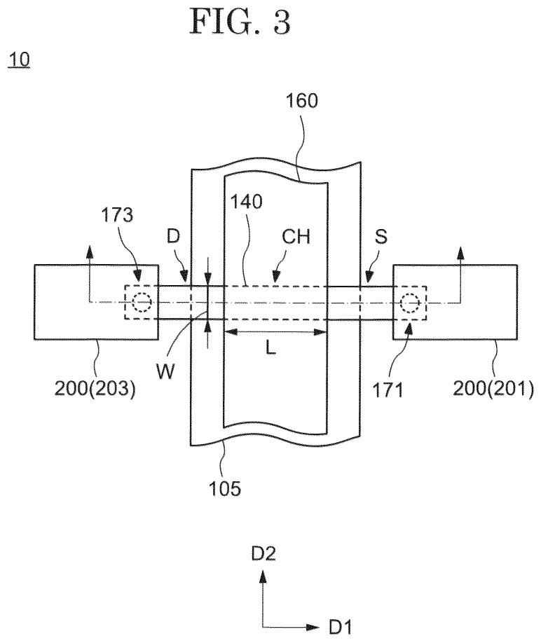

A thin film transistor according to an embodiment of the present invention will be described with reference to FIG. 2 to FIG. 3.

### 1. Configuration of Thin Film Transistor

FIG. 2 is a cross-sectional view showing an outline of a thin film transistor 10 according to an embodiment of the present invention. FIG. 3 is a plan view schematically showing the thin film transistor 10 according to an embodiment of the present invention.

As shown in FIG. 2, the thin film transistor 10 is arranged on the substrate 100. The thin film transistor 10 includes a gate electrode 105, the gate insulating layers 110 and 120, the metal oxide layer 130, the oxide semiconductor layer 140, the gate insulating layer 150, a gate electrode 160, insulating layers 170 and 180, a source electrode 201, and a drain electrode 203. If the source electrode 201 and the drain electrode 203 are not particularly distinguished from each other, they may be collectively referred to as a source/drain electrode 200.

In the present embodiment, the gate insulating layers 110 and 120 correspond to the base insulating layer 11 shown in FIG. 1, the metal oxide layer 130 corresponds to the metal oxide layer 130 shown in FIG. 1, and the oxide semiconductor layer 140 corresponds to the oxide semiconductor layer 140 shown in FIG. 1. Therefore, a laminated structure of the gate insulating layers 110 and 120, the metal oxide layer 130, and the oxide semiconductor layer 140 correspond to the laminated structure 1 shown in FIG. 1. Therefore, the oxide semiconductor layer 140 has the region 140a in which the same metal element as the metal element contained in the metal oxide layer 130 has the concentration gradient, and the concentration gradient of the metal element increases as it approaches the interface between the metal oxide layer and the oxide semiconductor layer 140. In the present embodiment, the thin film transistor 10 includes the laminated structure 1.

The gate electrode 105 is arranged on the substrate 100. The gate insulating layer 110 and the gate insulating layer 120 are arranged on the substrate 100 and the gate electrode 105. The metal oxide layer 130 is arranged on the gate insulating layer 120. The metal oxide layer 130 is in contact with the gate insulating layer 120. The oxide semiconductor layer 140 is arranged on the metal oxide layer 130. The oxide semiconductor layer 140 is in contact with the metal oxide layer 130. Within the main surface of the oxide semiconductor layer 140, a surface in contact with the metal oxide layer 130 is referred to as a lower surface 142. An end of the metal oxide layer 130 and an end of the oxide semiconductor layer 140 substantially coincide.

In the thin film transistor 10 according to the present embodiment, no semiconductor layer or oxide semiconductor layer is arranged between the metal oxide layer 130 and the substrate 100.

In FIG. 2, the sidewalls of the metal oxide layer 130 and the sidewalls of the oxide semiconductor layer 140 are arranged in a straight line, but the configuration is not limited to this. The angle of the sidewalls of the metal oxide layer 130 with respect to the main surface of the substrate 100 may be different from the angle of the sidewalls of the oxide semiconductor layer 140. The cross-sectional shapes of the sidewalls of at least one of the metal oxide layer 130 and the oxide semiconductor layer 140 may be curved.

The gate electrode 160 faces the oxide semiconductor layer 140. The gate insulating layer 150 is arranged between the oxide semiconductor layer 140 and the gate electrode 160. The gate insulating layer 150 is in contact with the oxide semiconductor layer 140. Within the main surface of the oxide semiconductor layer 140, the surface in contact with the gate insulating layer 150 is referred to as an upper surface 141. A surface between the upper surface 141 and the lower surface 142 is referred to as a side surface 143. The insulating layers 170 and 180 are arranged on the gate insulating layer 150 and the gate electrode 160. Openings 171 and 173 which expose the oxide semiconductor layer 140 are arranged in the insulating layers 170 and 180. The source electrode 201 is arranged to fill the inside of the opening 171. The source electrode 201 is in contact with the oxide semiconductor layer 140 at the bottom of the opening 171. The drain electrode 203 is arranged to fill the inside of the opening 173. The drain electrode 203 is in contact with the oxide semiconductor layer 140 at the bottom of the opening 173.

The gate electrode 105 has a function as a bottom gate of the thin film transistor 10 and a function as a light-shielding film for the oxide semiconductor layer 140. The gate insulating layer 110 functions as a barrier film that shields impurities diffusing from the substrate 100 toward the oxide semiconductor layer 140. The gate insulating layers 110 and 120 have a function as a gate insulating layer for the bottom gate. The metal oxide layer 130 is a layer containing a metal oxide containing aluminum as a main component, and not only improves the crystallinity of the oxide semiconductor layer 140 but also functions as a gas barrier film for shielding gases such as oxygen and hydrogen.

The oxide semiconductor layer 140 is divided into a source region S, a drain region D, and a channel region CH. The channel region CH is a region of the oxide semiconductor layer 140 vertically below the gate electrode 160. The source region S is a region of the oxide semiconductor layer 140 that does not overlap the gate electrode 160 and is closer to the source electrode 201 than the channel region CH. The drain region D is a region of the oxide semiconductor layer 140 that does not overlap the gate electrode 160 and is closer to the drain region CH 203. The oxide semiconductor layer 140 in the channel region CH has the physical properties of a semiconductor. The oxide semiconductor layer 140 in the source region S and the drain region D has the physical properties of a conductor.

The gate electrode 160 functions as a top gate of the thin film transistor 10 and a light-shielding film for the oxide semiconductor layer 140. The gate insulating layer 150 has a function as a gate insulating layer for the top gate, and has a function of releasing oxygen by a heat treatment in a manufacturing process. The insulating layers 170 and 180 have a function of insulating the gate electrode 160 and the source/drain electrode 200 and reducing parasitic capacitance therebetween. The operation of the thin film transistor 10 is controlled mainly by a voltage supplied to the gate electrode 160. An auxiliary voltage is supplied to the gate electrode 105. However, in the case where the gate electrode 105 is simply used as the light-shielding film, the gate electrode 105 may not be supplied with a particular voltage and may be floating. That is, the gate electrode 105 may simply be referred to as the “light-shielding film.”

The oxide semiconductor layer 140 has a thickness of at least 15 nm or more. In the oxide semiconductor layer 140, the region 140a in which the same metal element as the metal element contained in the metal oxide layer 130 has the concentration gradient is a region less than 14 nm from the interface with the metal oxide layer 130 in the thickness direction of the oxide semiconductor layer 140. The region 140a is a region that is hardly crystallized immediately after the oxide semiconductor layer 140 is deposited due to the influence of the metal oxide layer 130. In addition, the metal element contained in the metal oxide layer 130 has an action of widening the band gap of the oxide semiconductor layer 140. Furthermore, in the thickness direction of the oxide semiconductor layer 140, the region 140b which is 1 nm or more from the surface of the oxide semiconductor layer 140 is a region where the metal element has no concentration gradient. As described above, the oxide semiconductor layer 140 can have different band gaps between the region 140b (front-channel side) close to the gate electrode 160 and the region 140a (back-channel side) close to the metal oxide layer 130. It is known that in the Hall-effect measurement of the oxide semiconductor, the mobility increases with an increase in the volume density of a carrier. By limiting the generation region of free carriers generated by applying a voltage to a gate electrode of the transistor to the region 140b, the volume density of the free carrier increases and the mobility increases. Therefore, in the laminated structure 1 according to an embodiment of the present invention, it is presumed that the oxide semiconductor layer 140 also has a high mobility. In addition, the mobility in the present specification and the like means the field-effect mobility in a saturated region of the thin film transistor 10, which is a maximum value of the field-effect mobility in a region where a value (Vg-Vth) obtained by subtracting a threshold voltage (Vth) from a voltage (Vg) supplied to the thin film transistor 10 is smaller than a potential difference (Vd) between the source electrode and the drain electrode.

The oxide semiconductor layer 140 contains indium and at least one metal element excluding indium, and the metal oxide layer 130 includes a region containing indium.

The indium contained in the metal oxide layer 130 has the concentration gradient, and the concentration gradient of indium increases as it approaches the interface between the metal oxide layer 130 and the oxide semiconductor layer 140.

Although the present embodiment exemplifies a configuration in which a dual-gate transistor in which the gate electrode is arranged both above and below the oxide semiconductor layer 140 is used as the thin film transistor 10, the present invention is not limited to this configuration. For example, a top-gate transistor in which the gate electrode is arranged only above the oxide semiconductor layer 140 may be used as the thin film transistor 10. The above configuration is merely an embodiment, and the present invention is not limited to the above configuration.

As shown in FIG. 3, in a plan view, a planar pattern of the metal oxide layer 130 is substantially the same as a planar pattern of the oxide semiconductor layer 140. Referring to FIG. 2 and FIG. 3, the lower surface 142 of the oxide semiconductor layer 140 is covered with the metal oxide layer 130. In particular, in the thin film transistor 10 according to the present embodiment, all of the lower surface 142 of the oxide semiconductor layer 140 is covered with the metal oxide layer 130. In a direction D1, a width of the gate electrode 105 is greater than a width of the gate electrode 160. The direction D1 is a direction connecting the source electrode 201 and the drain electrode 203, and is a direction indicating a channel length L of the thin film transistor 10. Specifically, a length of a region where the oxide semiconductor layer 140 and the gate electrode 160 overlap (the channel region CH) in the direction D1 is the channel length L, and a width of the channel region CH in a direction D2 is the channel width W.

In the present embodiment, the configuration in which all of the lower surface 142 of the oxide semiconductor layer 140 is covered with the metal oxide layer 130 has been exemplified, but the configuration is not limited to this configuration. For example, part of the lower surface 142 of the oxide semiconductor layer 140 may not be in contact with the metal oxide layer 130. For example, all of the lower surface 142 of the oxide semiconductor layer 140 in the channel region CH may be covered with the metal oxide layer 130, and all or part of the lower surface 142 of the oxide semiconductor layer 140 in the source region S and the drain region D may not be covered with the metal oxide layer 130. That is, all or part of the lower surface 142 of the oxide semiconductor layer 140 in the source region S and the drain region D may not be in contact with the metal oxide layer 130. However, in the above configuration, part of the lower surface 142 of the oxide semiconductor layer 140 in the channel region CH may not be covered with the metal oxide layer 130, and another part of the lower surface 142 may be in contact with the metal oxide layer 130.

In the present embodiment, the configuration in which the gate insulating layer 150 is formed on the entire surface, and the openings 171 and 173 are arranged in the gate insulating layer 150 has been exemplified, but the configuration is not limited to this configuration. The gate insulating layer 150 may be patterned. For example, the gate insulating layer 150 may be patterned to expose not only the upper surface of the oxide semiconductor layer 140 but also the side surface of the oxide semiconductor layer 140.

In FIG. 3, a configuration in which the source/drain electrode 200 does not overlap the gate electrodes 105 and 160 is exemplified in a plan view, but the configuration is not limited to this configuration. For example, in a plan view, the source/drain electrode 200 may overlap at least one of the gate electrodes 105 and 160. The above configuration is merely an embodiment, and the present invention is not limited to the above configuration.

### 2. Material of Each member of Laminated Structure 1 and Thin Film Transistor 10

Since the material of each member of the laminated structure 1 is as described in the first embodiment, a description is provided with appropriate omissions.

The material of the substrate 100 described in the laminated structure 1 can be applied as the substrate 100. In the case where the thin film transistor 10 is a pixel transistor included in a display device such as a top-emission OLED, the substrate 100 does not need to be transparent, so that an impurity that decreases the transparency of the substrate 100 may be used. In the case where the thin film transistor 10 is used for an integrated circuit other than a display device, a substrate that does not have light transmittance, such as a semiconductor substrate such as a silicon substrate, a silicon carbide substrate, and a compound semiconductor substrate, or a conductive substrate such as a stainless substrate are used as the substrate 100.

General metal materials are used as the gate electrode 105, the gate electrode 160, and the source/drain electrode 200. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), these alloys or these compounds are used as these members. The above-described materials may be used in a single layer or in a stacked layer as the gate electrode 105, the gate electrode 160, and the source/drain electrode 200.

The material of the base insulating layer 11 described in the laminated structure 1 can be used as the gate insulating layers 110 and 120. A general insulating material is used as the insulating layers 170 and 180. For example, an inorganic insulating layer such as silicon oxide (SiOₓ), silicon oxynitride (SiOₓN_{y}), silicon nitride (SiNₓ), or silicon nitride oxide (SiNₓO_{y}) is used as the insulating layer. The above materials may be used in a single layer or in a stacked layer.

The insulating layer containing oxygen among the above-described insulating layers is used as the gate insulating layer 150. For example, an inorganic insulating layer such as silicon oxide (SiOₓ) or silicon oxynitride (SiOₓN_{y}) is used as the gate insulating layer 150.

An insulating layer having a function of releasing oxygen by the heat treatment is preferably used as the gate insulating layer 120. For example, the temperature of the heat treatment at which the gate insulating layer 120 releases oxygen is 600°° C. or lower, 500° C. or lower, 450° C. or lower, or 400° C. or lower. That is, for example, the gate insulating layer 120 emits oxygen at the heat treatment temperature performed in the manufacturing process of the thin film transistor 10 when the glass substrate is used as the substrate 100.

It is preferable to use an insulating layer with few defects as the gate insulating layer 150. For example, in the case where the composition ratio of oxygen in the gate insulating layer 150 is compared with the composition ratio of oxygen in an insulating layer having a composition similar to that of the gate insulating layer 150 (hereinafter referred to as “other insulating layer”), the composition ratio of oxygen in the gate insulating layer 150 is closer to the stoichiometric ratio with respect to the insulating layer than the composition ratio of oxygen in the other insulating layer. Specifically, in the case where silicon oxide (SiOₓ) is used for each of the gate insulating layer 150 and the insulating layer 180, the composition ratio of oxygen in the silicon oxide used as the gate insulating layer 150 is closer to the stoichiometric ratio of silicon oxide than the composition ratio of oxygen in the silicon oxide used as the insulating layer 180. For example, a layer in which no defects are observed when evaluated by an electron-spin resonance (ESR) may be used as the gate insulating layer 150.

The material of the metal oxide layer 130 described in the laminated structure 1 can be used as the metal oxide layer 130. For example, a metal oxide containing aluminum as a main component is used as the metal oxide layer 130. For example, an inorganic insulating layer such as aluminum oxide (AlOₓ), aluminum oxynitride (AlOₓN_{y}b), aluminum nitride oxide (AlNₓO_{y}), or aluminum nitride (AlNₓ) is used as the metal oxide layer 130. The “metal oxide layer containing aluminum as a main component” means that the proportion of aluminum contained in the metal oxide layer 130 is 1% or more of the entire metal oxide layer 130. The proportion of aluminum contained in the metal oxide layer 130 may be 5% or more and 70% or less, 10% or more and 60% or less, or 30% or more and 50% or less of the entire metal oxide layer 130. The ratio may be a mass ratio or a weight ratio.

An oxide semiconductor layer having crystallinity can be used as the oxide semiconductor layer 140. In the oxide semiconductor having crystallinity, an oxygen vacancy is less likely to be formed than in the amorphous oxide semiconductor.

### 3. Method for Manufacturing Laminated Structure 1 and Thin Film Transistor 10

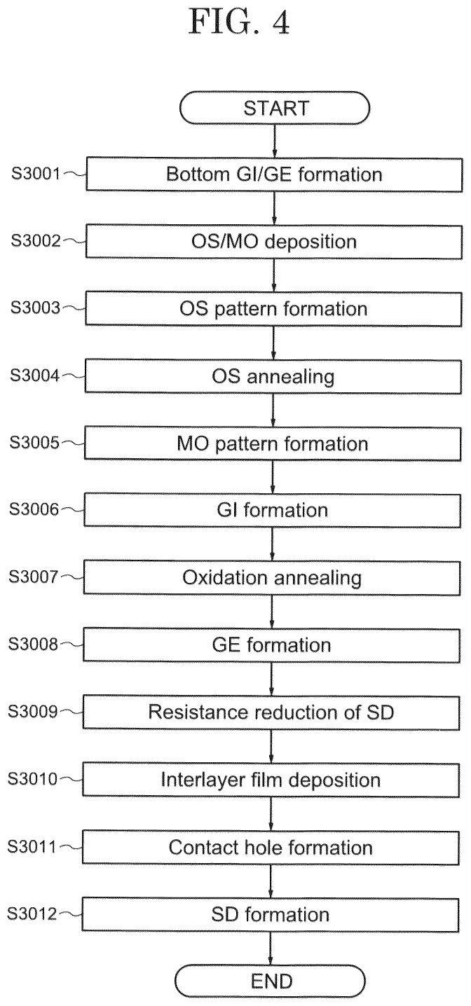

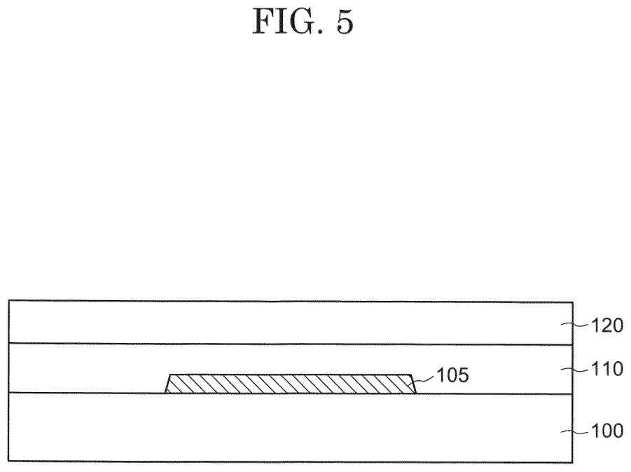

Next, a method for manufacturing a laminated structure 1 and the thin film transistor 10 will be described. FIG. 4 is a flowchart showing the method for manufacturing the laminated structure 1 and the thin film transistor 10 according to an embodiment of the present invention. FIG. 5 to FIG. 12 are cross-sectional views showing a method for manufacturing the laminated structure 1 and the thin film transistor 10 according to an embodiment of the present invention.

First, the method for manufacturing the laminated structure 1 according to an embodiment of the present invention will be described. As shown in FIG. 4 and FIG. 5, the gate electrode 105 is formed as the bottom gate on the substrate 100, and the gate insulating layers 110 and 120 are formed on the gate electrode 105 (“Bottom GI/GE formation” in step S3001 of FIG. 4). For example, silicon nitride is formed as the gate insulating layer 110. For example, silicon oxide is formed as the gate insulating layer 120. The gate insulating layers 110 and 120 are deposited by a CVD (Chemical Vapor Deposition) method.

Since silicon nitride is used as the gate insulating layer 110, the gate insulating layer 110 can block an impurity diffusing, for example, from the substrate 100 toward the oxide semiconductor layer 140. The silicon oxide used as the gate insulating layer 120 is a physical silicon oxide that releases oxygen by the heat treatment.

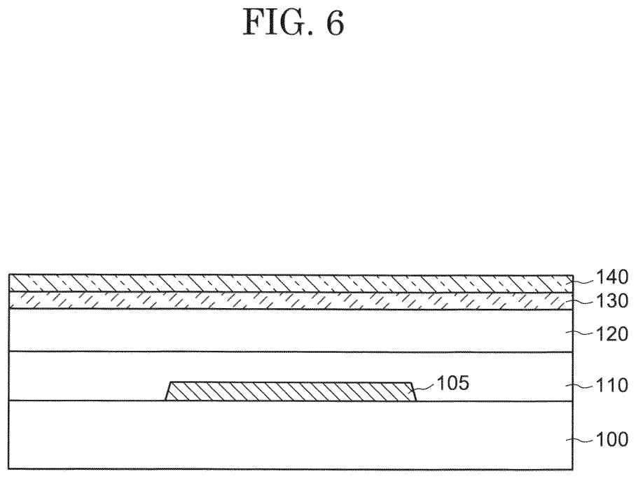

As shown in FIG. 4 and FIG. 6, the metal oxide layer 130 and the oxide semiconductor layer 140 are formed on the gate insulating layer 120 (“OS/MO deposition” in step S3002 of FIG. 4). The metal oxide layer 130 is deposited by the sputtering method or an atomic layer deposition method (ALD).

For example, the thickness of the metal oxide layer 130 is 1 nm or more and 100 nm or less, 1 nm or more and 50 nm or less, 1 nm or more and 30 nm or less, or 1 nm or more and 10 nm or less. In the present embodiment, aluminum oxide is used as the metal oxide layer 130. Aluminum oxide has a high barrier property against gas. In the present embodiment, the aluminum oxide used as the metal oxide layer 130 blocks hydrogen and oxygen released from the gate insulating layer 120 and suppresses the released hydrogen and oxygen from reaching the oxide semiconductor layer 140.

Next, the oxide semiconductor layer 140 is formed on the metal oxide layer 130. For example, the thickness of the oxide semiconductor layer 140 is 15 nm or more and 100 nm or less, 15 nm or more and 70 nm or less, or 15 nm or more and 40 nm or less. If the thickness of the oxide semiconductor layer 140 is less than 15 nm, the oxide semiconductor layer 140 tends not to be crystallized. Therefore, the thickness of the oxide semiconductor layer 140 is preferably at least 15 nm or more. In the case where the oxide semiconductor layer 140 is crystallized by OS annealing described later, the oxide semiconductor layer 140 after deposition and before the OS annealing is preferably a film having a small crystal component, and is particularly preferably amorphous (state in which the oxide semiconductor contains a small amount of crystal components). That is, a deposition condition of the oxide semiconductor layer 140 is preferably a condition such that the oxide semiconductor layer 140 immediately after deposition does not crystallize as much as possible.

In the deposition by sputtering, since ions generated in the plasma and atoms recoiled by the sputtering target collide with the substrate, even if the substrate temperature at the beginning of sputtering is room temperature, the substrate temperature increases during deposition. When the substrate temperature increases during deposition, microcrystals are likely to be contained in the oxide semiconductor layer immediately after deposition. Therefore, the deposition of the oxide semiconductor layer is preferably performed while controlling the substrate temperature. For example, the substrate temperature is 100° C. or lower, preferably 70° C. or lower, and more preferably 50° C. or lower. The substrate temperature may be 30° C. or lower. For example, the substrate temperature can be controlled by cooling the substrate. In addition, the oxide semiconductor layer may be deposited at a deposition rate where the substrate temperature does not exceed a predetermined temperature. Furthermore, the substrate temperature may be controlled by increasing a distance between the target and the substrate so that the substrate is not affected by the sputtering target.

Furthermore, in the sputtering process, the oxide semiconductor layer is deposited under conditions of an oxygen partial pressure of 10% or less. When the oxygen partial pressure is high, the oxide semiconductor layer immediately after deposition is likely to contain microcrystals due to excessive oxygen in the oxide semiconductor layer. For this reason, the deposition of the oxide semiconductor layer is preferably performed under conditions where the partial pressure of oxygen is low. For example, the oxygen partial pressure is greater than 2% and 20% or less, preferably 3% or more and 15% or less, and more preferably 3% or more and 10% or less. Furthermore, in the case where the oxide semiconductor layer is deposited at a partial pressure of 2% or less, the oxide semiconductor layer does not crystallize even after the annealing process.

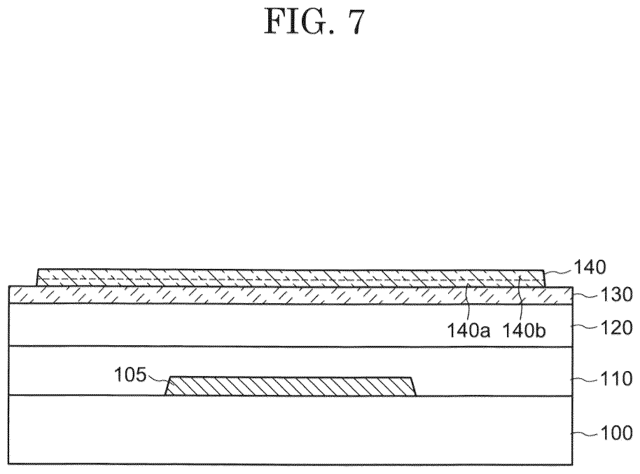

As shown in FIG. 4 and FIG. 7, a pattern of the oxide semiconductor layer 140 is formed (“OS pattern formation” in step S3003 of FIG. 4). Although not shown, a resist mask is formed on the oxide semiconductor layer 140, and the oxide semiconductor layer 140 is etched using the resist mask. Wet etching may be used, or dry etching may be used as the etching of the oxide semiconductor layer 140. Etching can be performed using an acidic etchant as the wet etching. For example, oxalic acid, PAN, sulfuric acid, hydrogen peroxide solution, or hydrofluoric acid can be used as the etchant.

After the pattern of the oxide semiconductor layer 140 is formed, the heat treatment (OS annealing) is performed on the oxide semiconductor layer 140 (“OS annealing” in step S3004 of FIG. 4). In the present embodiment, the oxide semiconductor layer 140 is crystallized by the OS annealing.

In the OS annealing, the oxide semiconductor layer 140 is held at a predetermined reached temperature for a predetermined time. The predetermined reached temperature is 300° C. or higher and 500° C. or lower, preferably 350° C. or higher and 450° C. or lower. In addition, the holding time at the reached temperature is 15 minutes or more and 120 minutes or less, preferably 30 minutes or more and 60 minutes or less. By performing the OS annealing, the oxide semiconductor layer 140 is crystallized, and the oxide semiconductor layer 140 having the polycrystalline structure is formed.

By performing the OS annealing, the metal element contained in the metal oxide layer 130 diffuses into the oxide semiconductor layer 140 in the process of crystallizing the oxide semiconductor layer 140. As a result, the oxide semiconductor layer 140 has the region 140a in which the same metal element as the metal element contained in the metal oxide layer has the concentration gradient, and the concentration gradient of the metal element increases as it approaches the interface between the metal oxide layer and the oxide semiconductor layer 140.

As described above, the metal element contained in the metal oxide layer 130 is a metal element having an action of widening the band gap. When the metal element contained in the metal oxide layer 130 is diffused into the oxide semiconductor layer 140, the band gap is widened in the region 140a where the metal element is diffused. As a result, the region 140a in which the metal element is diffused in the oxide semiconductor layer 140 becomes a region acting like an insulator.

In the thin film transistor, by reducing the thickness of the oxide semiconductor layer, the carrier in the vicinity of the interface with the gate insulating layer is increased, and the effect of the back channel is reduced, so that the field-effect mobility tends to be high. In other words, the thin film transistor tends to have higher field-effect mobility as a thickness of a region functioning as the channel of the oxide semiconductor layer decreases. Therefore, the smaller the thickness of the oxide semiconductor layer, the better. However, there is a tendency for the oxide semiconductor layer not to crystallize satisfactorily even if the annealing process is performed after the thickness of the oxide semiconductor layer is formed at less than 15 nm. If the oxide semiconductor layer does not crystallize well, the oxide semiconductor layer and the metal oxide layer disappear during the etching process for patterning the oxide semiconductor layer later. Therefore, it is difficult to achieve both thinning of the oxide semiconductor layer and good crystallization.

According to the laminated structure 1 according to an embodiment of the present invention, the oxide semiconductor layer 140 has the region 140a in which the same metal element as the metal element contained in the metal oxide layer 130 has the concentration gradient. In addition, the concentration gradient of the metal element increases as it approaches the interface between the metal oxide layer 130 and the oxide semiconductor layer 140.

The oxide semiconductor layer 140 has a thickness of at least 15 nm or more. In the oxide semiconductor layer 140, the region 140a in which the same metal element as the metal element contained in the metal oxide layer 130 has the concentration gradient is a region less than 14 nm from the interface with the metal oxide layer 130 in the thickness direction of the oxide semiconductor layer 140. The region 140a is a region that is hardly crystallized immediately after the oxide semiconductor layer 140 is deposited due to the influence of the metal oxide layer 130. In addition, the metal element contained in the metal oxide layer 130 has an action of widening the band gap of the oxide semiconductor layer 140. Therefore, in the oxide semiconductor layer, the region 140a in which the metal element has the concentration gradient can be a region acting as an insulator.

When the oxide semiconductor layer is deposited, the oxide semiconductor layer 140 can be formed with a thickness of 15 nm or more. Therefore, the oxide semiconductor layer 140 can be satisfactorily crystallized in the annealing process. That is, in the oxide semiconductor layer 140, after the film is formed to have a thickness capable of crystallization, the metal element contained in the metal oxide layer 130 is diffused into the oxide semiconductor layer in the annealing process. As a result, the region 140a acting as an insulator can be formed in in the oxide semiconductor layer 140. Therefore, in the oxide semiconductor layer 140, the thickness of the region 140b acting as a semiconductor material can be substantially reduced.

Furthermore, in the thickness direction of the oxide semiconductor layer 140, the region 140b from the surface of the oxide semiconductor layer 140 to the region 140a is a region where the metal element has no concentration gradient. As described above, the oxide semiconductor layer 140 can have different band gaps between the region 140b (front-channel side) close to the gate electrode 160 and the region 140a (back-channel side) close to the metal oxide layer 130. As a result, the oxide semiconductor layer 140 can concentrate the free carriers in the region 140b close to the gate electrode 160. Therefore, the field-effect mobility of the thin film transistor 10 can be improved. Therefore, in the laminated structure 1 according to an embodiment of the present invention, it is presumed that the oxide semiconductor layer 140 also has a high mobility.

In addition, by performing the OS annealing, indium contained in the oxide semiconductor layer 140 may diffuse into the metal oxide layer 130. As a result, the metal oxide layer 130 has a region containing indium. Indium contained in the metal oxide layer 130 has the concentration gradient, and the concentration gradient of indium increases as it approaches the interface between the metal oxide layer 130 and the oxide semiconductor layer 140.

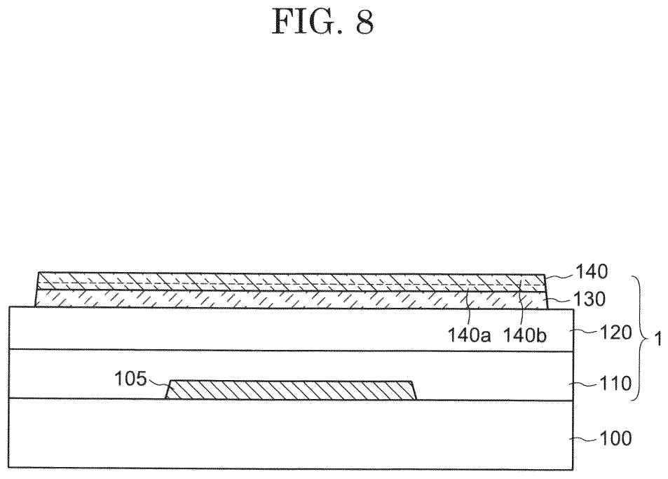

As shown in FIG. 4 and FIG. 8, a pattern of the metal oxide layer 130 is formed (“MO pattern formation” in step S3005 of FIG. 4). The metal oxide layer 130 is etched using the oxide semiconductor layer 140 patterned in the above-described process as a mask. Wet etching may be used, or dry etching may be used as the etching of the metal oxide layer 130. For example, dilute hydrofluoric acid (DHF) is used as the wet etching. As described above, the photolithography process can be omitted by etching the metal oxide layer 130 using the oxide semiconductor layer 140 as a mask.

Through the above steps, the laminated structure 1 shown in FIG. 1 can be manufactured. In the method for manufacturing the laminated structure 1, the step of forming the patterned metal oxide layer 130 may be omitted.

Next, a method for manufacturing the thin film transistor 10 according to an embodiment of the present invention will be described. In the method for manufacturing the thin film transistor 10, the thin film transistor 10 is manufactured using the laminated structure 1 described above.

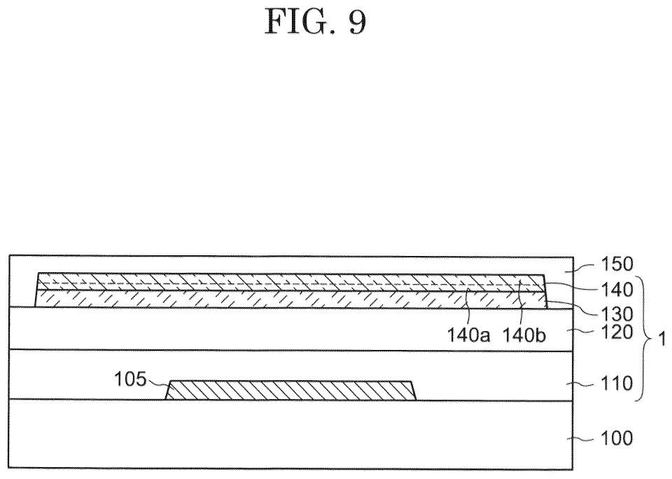

As shown in FIG. 4 and FIG. 9, the gate insulating layer 150 is deposited (“GI formation” in step S3006 of FIG. 4). For example, silicon oxide is formed as the gate insulating layer 150. The gate insulating layer 150 is formed by the CVD method. For example, the gate insulating layer 150 may be deposited at a deposition temperature of 350° C. or higher in order to form an insulating layer with few defects as described above as the gate insulating layer 150. For example, a thickness of the gate insulating layer 150 is 50 nm or more and 300 nm or less, 60 nm or more and 200 nm or less, or 70 nm or more and 150 nm or less. After the gate insulating layer 150 is deposited, an oxygen-implanting process may be performed on part of the gate insulating layer 150.

The heat treatment (oxidation annealing) is performed to supply oxygen to the oxide semiconductor layer 140 with the gate insulating layer 150 deposited on the oxide semiconductor layer 140 (“Oxidation annealing” in step S3007 of FIG. 4). In the process from the deposition of the oxide semiconductor layer 140 to the deposition of the gate insulating layer 150 on the oxide semiconductor layer 140, a large amount of oxygen vacancies occur in the upper surface 141 and the side surface 143 of the oxide semiconductor layer 140. The oxygen released from the gate insulating layers 120 and 150 is supplied to the oxide semiconductor layer 140 by the above-described oxidation annealing, and the oxygen vacancies are repaired.

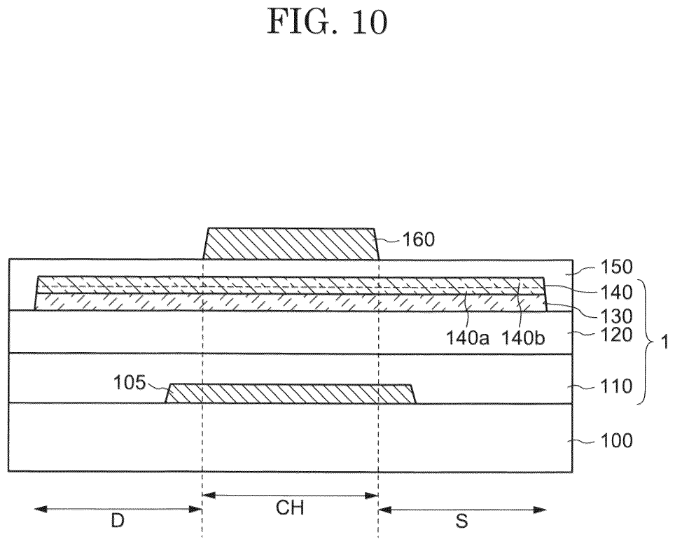

As shown in FIG. 4 and FIG. 10, the gate electrode 160 is deposited (“GE formation” in step S3008 of FIG. 4). The gate electrode 160 is deposited by the sputtering method or the atomic layer deposition method, and is patterned through the photolithography process.

With the gate electrode 160 patterned, the resistance of the source region S and the drain region D of the oxide semiconductor layer 140 is reduced (“Resistance reduction of SD” in step S3009 of FIG. 4). Specifically, an impurity is implanted into the oxide semiconductor layer 140 from the gate electrode 160 side via the gate insulating layer 150 by an ion implantation. By the ion implantation, for example, argon (Ar), phosphorus (P), and boron (B) are implanted into the oxide semiconductor layer 140. An oxygen vacancy is formed in the oxide semiconductor layer 140 by the ion implantation, thereby reducing the resistance of the oxide semiconductor layer 140. Since the gate electrode 160 is arranged above the oxide semiconductor layer 140 functioning as the channel region CH of the thin film transistor 10, the impurity is not implanted into the oxide semiconductor layer 140 in the channel region CH.

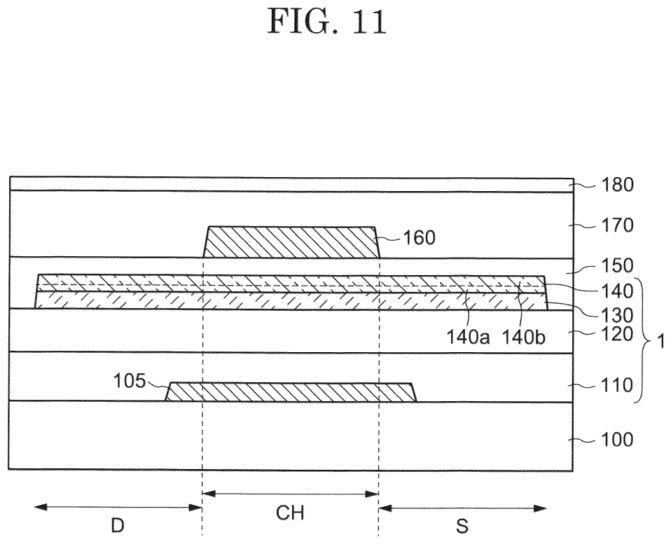

As shown in FIG. 4 and FIG. 11, the insulating layers 170 and 180 are formed as an interlayer film on the gate insulating layer 150 and the gate electrode 160 (“Interlayer film deposition” in step S3010 of FIG. 4). The insulating layers 170 and 180 are formed by the CVD method. For example, silicon nitride is formed as the insulating layer 170, and silicon oxide is formed as the insulating layer 180. The materials used for the insulating layers 170 and 180 are not limited to the above. A thickness of the insulating layer 170 is 50 nm or more and 500 nm or less. A thickness of the insulating layer 180 is 50 nm or more and 500 nm or less.

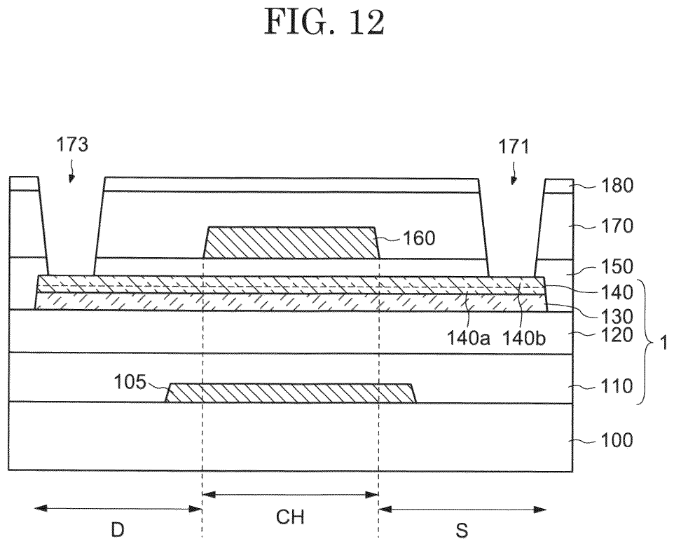

As shown in FIG. 4 and FIG. 12, the openings 171 and 173 are formed in the gate insulating layer 150 and the insulating layers 170 and 180 (“Contact hole formation” in step S3011 of FIG. 4). The oxide semiconductor layer 140 in the source region S is exposed by the opening 171. The oxide semiconductor layer 140 in the drain region D is exposed by the opening 173. Forming the source/drain electrode 200 on the oxide semiconductor layer 140 and on the insulating layer 180 exposed by the openings 171 and 173 (“SD formation” in step S3012 of FIG. 4) completes the thin film transistor 10 shown in FIG. 2.

In the thin film transistor 10 manufactured by the above-described manufacturing method, the thickness of the oxide semiconductor layer functioning as the channel can be substantially reduced. As a result, it is possible to obtain electrical characteristics having a mobility of 30 cm²/Vs or more, 35 cm²/Vs or more, 40 cm²/Vs or more, or 50 cm²/Vs or more in a range where the channel length L of the channel region CH is 2 μm or more and 4 μm or less and the channel width is 2 μm or more and 25 μm or less.

### Third Embodiment

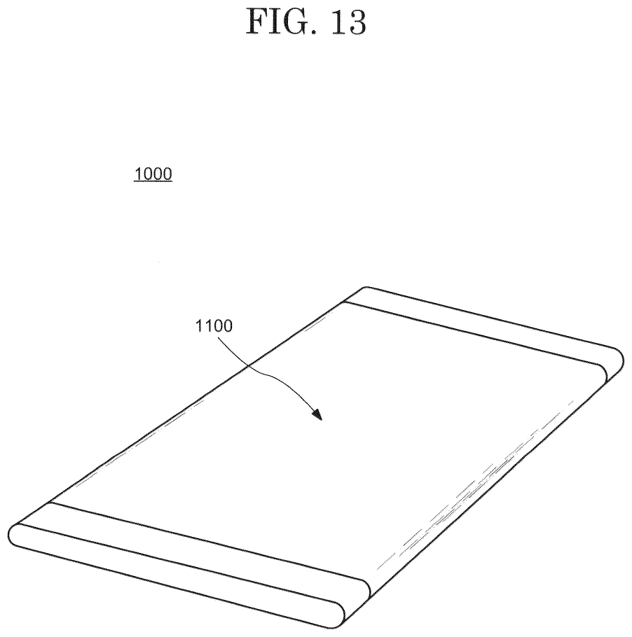

An electronic device according to an embodiment of the present invention will be described with reference to FIG. 13.

FIG. 13 is a schematic diagram showing an electronic device 1000 according to an embodiment of the present invention. Specifically, FIG. 13 shows a smartphone that is an example of the electronic device 1000. The electronic device 1000 includes a display device 1100 having a curved side surface. The display device 1100 includes a plurality of pixels for displaying an image, and the plurality of pixels is controlled by a pixel circuit, a drive circuit, and the like. The thin film transistor 10 described in the second embodiment is included in the pixel circuit and the drive circuit. Since the thin film transistor 10 has a high field-effect mobility, the responsiveness of the pixel circuit and the drive circuit can be improved, and as a result, the performance of the electronic device 1000 can be improved.

In addition, the electronic device 1000 according to the present embodiment is not limited to a smartphone. For example, the electronic device 1000 also includes an electronic device having a display device such as a watch, a tablet, a notebook computer, a car navigation system, or a TV. Furthermore, the oxide semiconductor layer described in the first embodiment or the thin film transistor 10 described in the second embodiment can be applied to any electronic device regardless of the presence or absence of the display device.

### EXAMPLES

In the present embodiment, the thin film transistor 10 according to an embodiment of the present invention is manufactured, and the results of verifying the concentration of the metal element in the oxide semiconductor layer 140 and the metal oxide layer 130 will be described.

### Example A

The thin film transistor 10 according to an embodiment of the present invention was manufactured as Example A. The thin film transistor 10 was manufactured according to the sequence diagram shown in FIG. 3. In this case, a glass substrate was used as the substrate, a silicon nitride film was used as the gate insulating layer 110, and a silicon oxide film was used as the gate insulating layer 120. In addition, a 10 nm aluminum oxide layer was used as the metal oxide layer 130. An oxide semiconductor having an atomic ratio of 70% of indium to all metal elements contained in the film and having a 30 nm polycrystalline structure was used as the oxide semiconductor layer 140. A silicon oxide film was used as the gate insulating layer 150.

### Comparative Example A

A thin film transistor without the metal oxide layer 130 was manufactured as a comparative example. The thin film transistor of Comparative Example A was manufactured according to the sequence diagram shown in FIG. 3 except that the metal oxide layer 130 was not formed. That is, MO deposition in step S3003 and MO pattern formation in step S3005 are omitted. Other configurations, thicknesses, deposition conditions, and the like are similar to those in Example A.

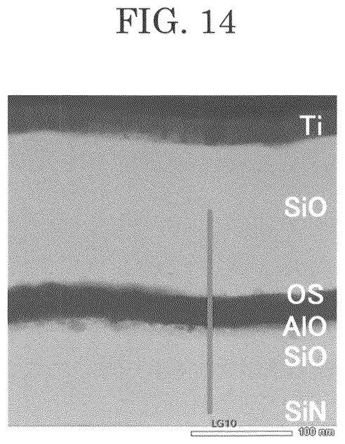

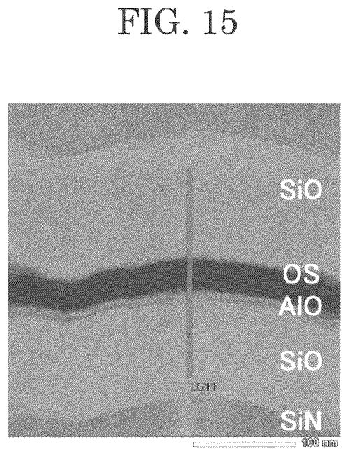

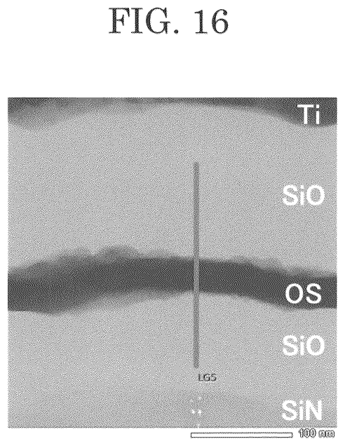

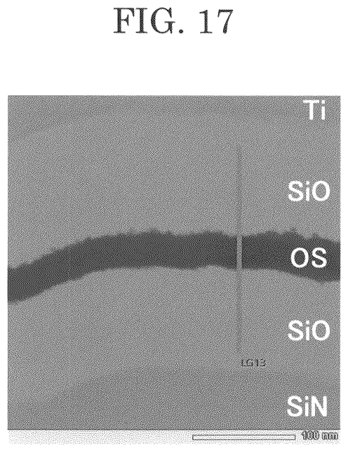

Cross-sectional STEM (Scanning Transmission Electron Microscopy) observation was performed on the thin film transistor 10 according to Example A and the thin film transistor according to Comparative Example A. FIG. 14 is a STEM image in the vicinity of the channel region of the thin film transistor in Example A, and FIG. 15 is a STEM image in the vicinity of the source region of the thin film transistor in Example A. FIG. 16 is a STEM image in the vicinity of the channel region of the thin film transistor in Comparative Example A, and FIG. 17 is a STEM image in the vicinity of the source region of the thin film transistor in Comparative Example A.

Next, the results of elemental analysis performed on the observation region in FIG. 14 to FIG. 17 using energy dispersive X-ray spectroscopy (EDX) will be described.

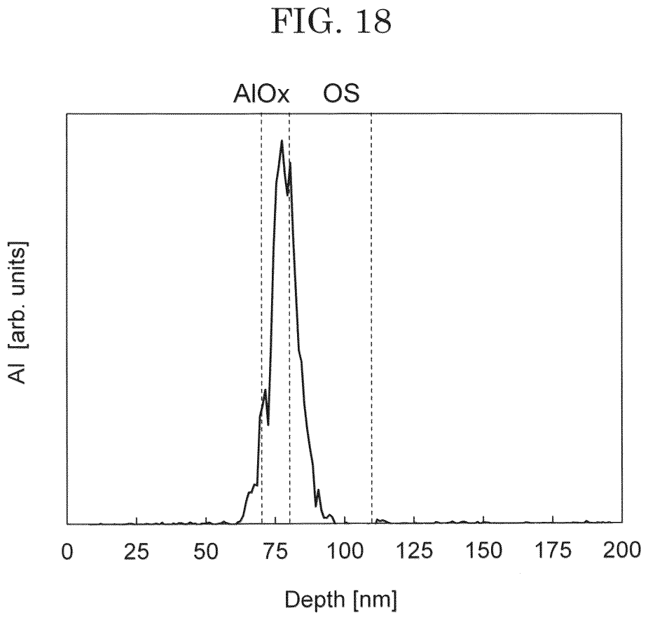

The results of EDX analysis of the constituent elements along the straight lines shown in the STEM images in FIG. 14 to FIG. 17 are shown in FIG. 18 to FIG. 21.

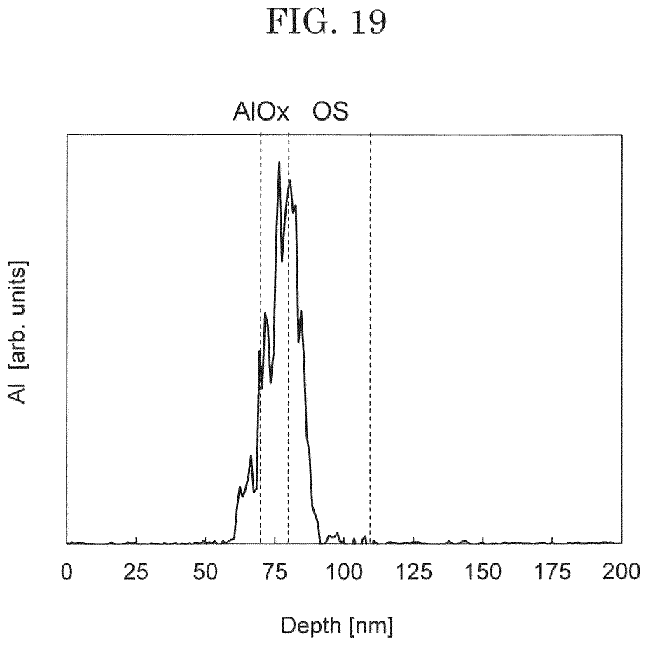

FIG. 18 shows the EDX analysis results of Al in the vicinity of the channel region of the thin film transistor in Example A. FIG. 19 shows the EDX analysis results of Al in the vicinity of the source region of the thin film transistor in Example A. In FIG. 18 and FIG. 19, an interface between the aluminum oxide layer and the oxide semiconductor layer has a depth (Depth) in the vicinity of 80 nm. The interface between the aluminum oxide layer and the oxide semiconductor layer is indicated by a dotted line. In addition, the thickness of the aluminum oxide layer and the thickness of the oxide semiconductor layer are indicated by dotted lines based on 80 nm.

As shown in FIG. 18 and FIG. 19, it can be seen that Al has the concentration gradient in the channel region and the source region of the thin film transistor in Example A. From FIG. 18 and FIG. 19, it can be seen that the region where Al has the concentration gradient is a region less than 15 nm from the interface with the metal oxide layer 130 in the thickness direction of the oxide semiconductor layer 140. Furthermore, in the thickness direction of the oxide semiconductor layer 140, the region of about 15 nm from the surface of the oxide semiconductor layer 140 is found to be a region where Al has no concentration gradient.

Next, in Example A, the results obtained by fitting the profile of Al obtained by the EDX analysis with the Gaussian function represented by Formula (2), the complementary error function represented by Formula (3), and the Lorentz function represented by Formula (4) will be described.

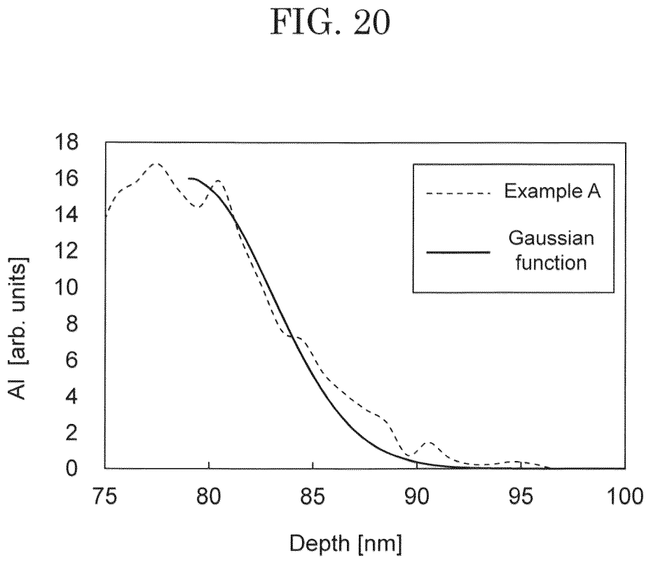

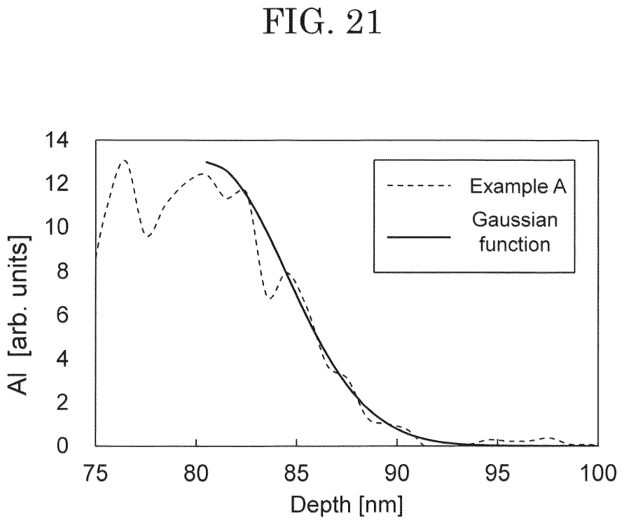

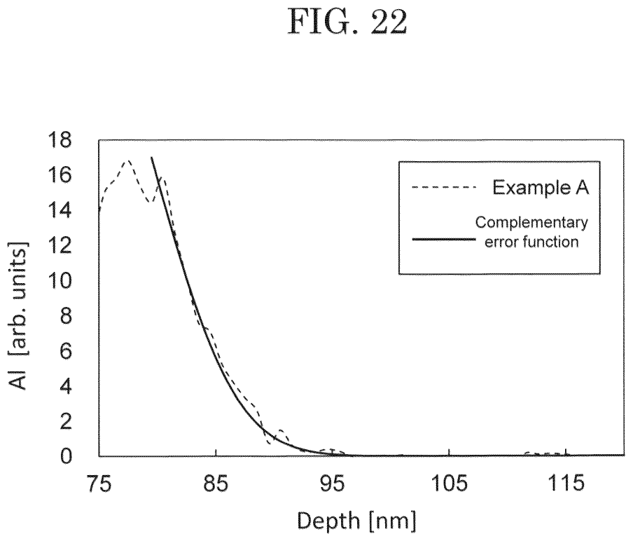

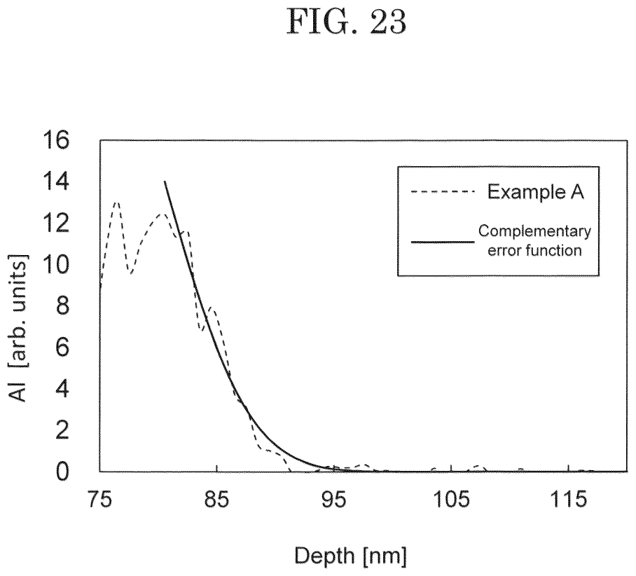

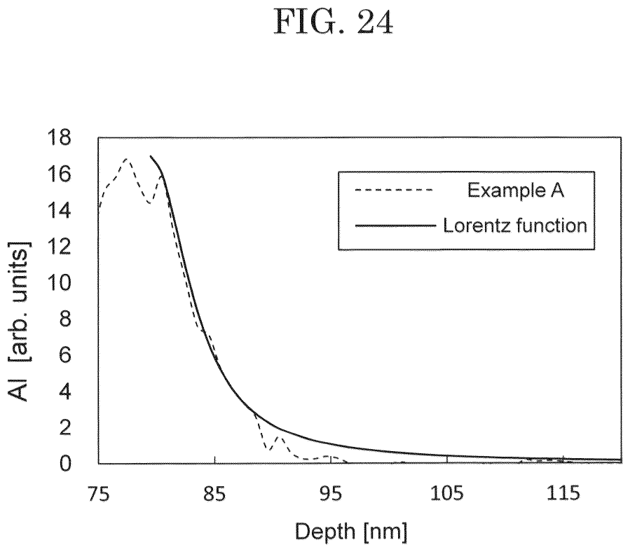

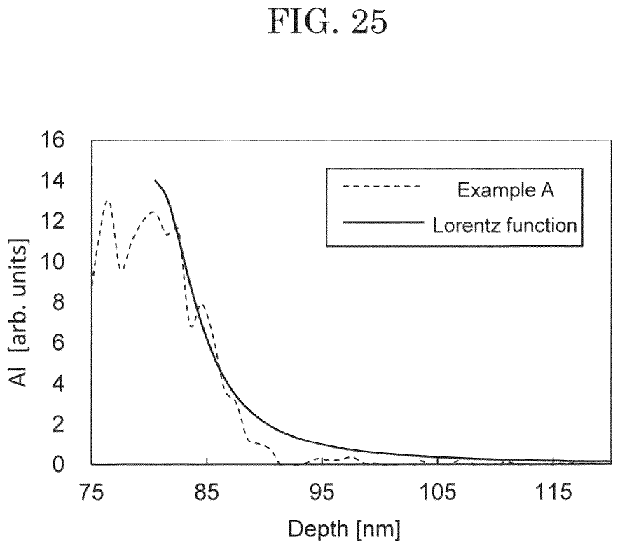

FIG. 20 is a graph obtained by fitting the profile of Al obtained by the EDX analysis in the channel region of Example A with the Gaussian function. FIG. 21 is a graph obtained by fitting the profile of Al obtained by the EDX analysis in the source region of Example A with the Gaussian function. FIG. 22 is a graph obtained by fitting the profile of Al obtained by the ESX analysis in the channel region of Example A with the complementary error function. FIG. 23 is a graph obtained by fitting the profile of Al obtained by the EDX analysis in the source region of Example A with the complementary error function. FIG. 24 is a graph obtained by fitting the profile of Al obtained by the EDX analysis in the channel region of Example A with the Lorentz function. FIG. 25 is a graph obtained by fitting the profile of Al obtained by the EDX analysis in the source region of Example A with the Lorentz function.

In FIG. 20 to FIG. 25, the fitting function in Example A is indicated by a solid line. The positive direction of the distance is a direction from the interface between the metal oxide layer 130 and the oxide semiconductor layer 140 toward the oxide semiconductor layer 140, and the negative direction of the distance is a direction from the interface between the metal oxide layer 130 and the oxide semiconductor layer 140 toward the metal oxide layer 130.

The value c (scale parameter or half width at half maximum) calculated by fitting the concentrations of Al in the channel region and the source region using each fitting function is shown in Table 1. Table 2 shows the thickness Ad converted from the calculated value c based on Δd=3c.

TABLE 1

| | Value c in fitting function | | |
|---|---|---|---|
| | Gaussian | Complementary | Lorentz |
| | function | function | function |
| Channel region | 4 nm | 4 nm | 4 nm |
| Source region | 4 nm | 4 nm | 4 nm |

TABLE 2

| | Thickness Δd converted from value c | | |
|---|---|---|---|
| | Gaussian | Complementary | Lorentz |
| | function | function | function |
| Channel region | 12 nm | 12 nm | 12 nm |
| Source region | 12 nm | 12 nm | 12 nm |

As shown in Table 2, the thickness Δd of the region with the concentration gradient of Al in the oxide semiconductor layer of Example A was 12 nm using any of the fitting functions. As explained in the first embodiment, not all of the thickness Δd of the region with the concentration gradient of Al acts like an insulator. In this case, a region with a thickness corresponding to c=4 nm is a region acting like an insulator. That is, it can be seen that the region with the thickness from the interface between the metal oxide layer and oxide semiconductor layer to 4 nm corresponds to the region 140a. In other words, the region 5 nm or more from the interface between the metal oxide layer and the oxide semiconductor layer is a region acting as a semiconductor.

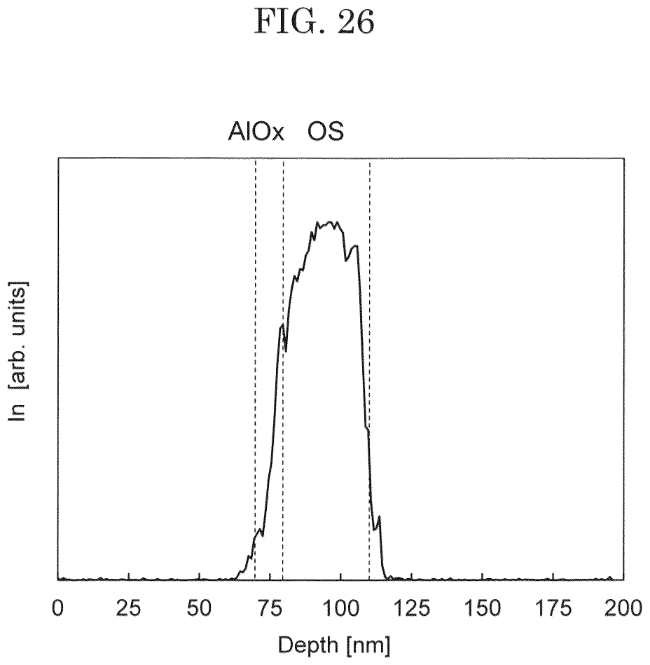

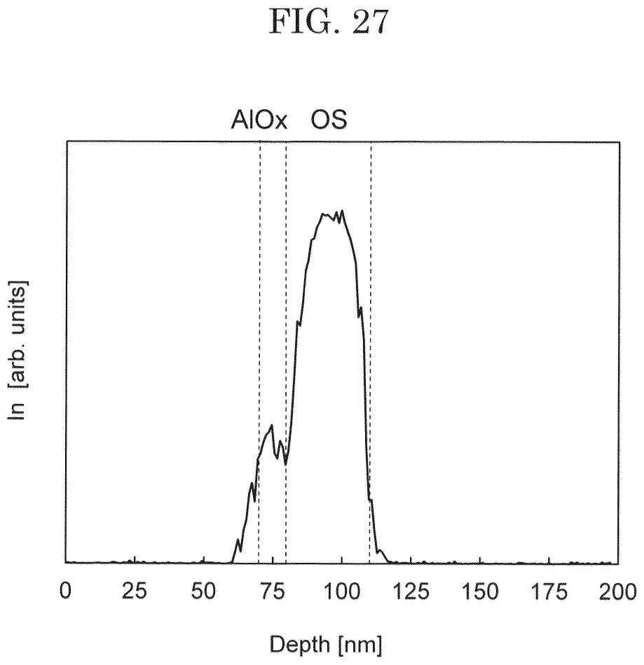

FIG. 26 shows the EDX analysis results of indium in the channel region of the thin film transistor in Example A. FIG. 27 shows the EDX analysis results of indium in the vicinity of the source region of the thin film transistor in Example A. In FIG. 26 and FIG. 27, the interface between the aluminum oxide layer and the oxide semiconductor layer in Example A has a depth of about 80 nm. The interface between the aluminum oxide layer and the oxide semiconductor layer is indicated by a dotted line. In addition, the thickness of the aluminum oxide layer and the thickness of the oxide semiconductor layer are indicated by dotted lines based on 80 nm.

As shown in FIG. 26 and FIG. 27, in the thin film transistor of Example A, the metal oxide layer 130 contains indium contained in the oxide semiconductor layer 140. It can be seen that indium contained in the metal oxide layer 130 has the concentration gradient, and the concentration gradient of indium increases as it approaches the interface between the metal oxide layer 130 and the oxide semiconductor layer 140.

As described above, in the thin film transistor according to the embodiment of the present invention, the oxide semiconductor layer has the region in which the same metal element as the metal element contained in the metal oxide layer has the concentration gradient, and the concentration gradient of the metal element increases as it approaches the interface between the metal oxide layer and oxide semiconductor layer. This suggests that the oxide semiconductor layer can be well crystallized and that the thickness acting as the channel can be substantially reduced. As a result, the carrier density can be increased in the region functioning as the channel. Therefore, it is considered that the field-effect mobility of the thin film transistor can be greatly increased.

Each of the embodiments described above as the embodiment of the present invention can be appropriately combined and implemented as long as no contradiction is caused. Furthermore, the addition, deletion, or design change of components, or the addition, deletion, or condition change of processes as appropriate by those skilled in the art based on each embodiment are also included in the scope of the present disclosure as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A laminated structure comprising:
a base insulating layer;
a metal oxide layer arranged on the base insulating layer; and
an oxide semiconductor layer in contact with the metal oxide layer, and having a polycrystalline structure;
wherein the oxide semiconductor layer includes a first region in which the same metal element as the metal element contained in the metal oxide layer has a concentration gradient and the concentration gradient of the metal oxide layer increases as it approaches the interface between the metal oxide layer and the oxide semiconductor layer.

2. The laminated structure according to claim 1, wherein
the oxide semiconductor layer has a thickness of at least 15 nm or more, and
the first region is a region less than 14 nm from the interface with the metal oxide layer in the thickness direction of the oxide semiconductor layer.

3. The laminated structure according to claim 1, wherein
the oxide semiconductor layer has a thickness of at least 15 nm, and
the oxide semiconductor layer has a second region which has no concentration gradient of the metal element on a side that does not contact the metal oxide layer, and
the second region is in contact with the first region and has a thickness of 1 nm or more in the thickness direction of the oxide semiconductor layer.

4. The laminated structure according to claim 1, wherein
the oxide semiconductor layer contains indium and at least one or more metal elements excluding indium, and
the metal oxide layer has a region containing indium.

5. The laminated structure according to claim 1, wherein
the oxide semiconductor includes a region where a ratio of indium to indium and at least one metal element is 50% or more.

6. The laminated structure according to claim 1, wherein
indium contained in the metal oxide layer has a concentration gradient, and the concentration gradient of indium increases as it approaches the interface between the metal oxide layer and the oxide semiconductor layer.

7. The laminated structure according to claim 1, wherein
the metal oxide layer contains a metal oxide with a band gap of 4.0 eV or more.

8. The laminated structure according to claim 1, wherein
the metal oxide layer contains one or more metal elements selected from aluminum (Al), magnesium (Mg), calcium (Ca), scandium (Sc), gallium (Ga), germanium (Ge), strontium (Sr), nickel (Ni), tantalum (Ta), yttrium (Y), zirconium (Zr), barium (Ba), hafnium (Hf), cobalt (Co), and lanthanoid-based elements.

9. The laminated structure according to claim 1, wherein
the oxide semiconductor layer has a bixbyite-type crystal structure.

10. A thin film transistor comprising:
the laminated structure according to claim 1;
a gate insulating film arranged on the oxide semiconductor layer; and
a gate electrode arranged on the gate insulating film so as to overlap at least a part of the oxide semiconductor layer.
